(19) United States
(12) Patent Application Publication
(10) Pub. No.: US 2017/0294365 A1
(43) Pub. Date: Oct. 12, 2017

(54) SEMICONDUCTOR DEVICE

(71) Applicant: SUMITOMO ELECTRIC INDUSTRIES, LTD., Osaka (JP)

(72) Inventor: Masataka WATANABE, Yokohama-shi (JP)

(73) Assignee: SUMITOMO ELECTRIC INDUSTRIES, LTD., Osaka (JP)

(21) Appl. No.: 15/476,490

(22) Filed: Mar. 31, 2017

(30) Foreign Application Priority Data
Apr. 11, 2016 (JP) 2016-079018

(51) Int. Cl. H01L 23/31; H01L 23/29; H01L 23/00; H01L 29/20

(52) U.S. Cl. CPC H01L 23/3171; H01L 29/20; H01L 23/3192; H01L 23/293; H01L 23/291; H01L 24/05; H01L 29/7371

(57) ABSTRACT

A semiconductor device includes: a semiconductor element disposed on a semiconductor substrate; a first insulating film disposed on the semiconductor substrate, the first insulating film having an upper surface and an edge; a resin layer disposed on the semiconductor substrate, the resin layer covering the semiconductor element; and a second insulating film disposed on the semiconductor substrate, the second insulating film covering the upper and side surfaces of the resin layer, wherein the second insulating film has an edge arranged apart from the side surface of the resin layer by a distance, and the distance between the edge of the second insulating film and the side surface of the resin layer is greater than a film thickness of the second insulating film.

### CROSS-REFERENCE TO RELATED APPLICATION

This application is based upon and claims the benefit of priority of the prior Japanese Patent Applications No. 2016-079018, filed on Apr. 11, 2016, the entire contents of which are incorporated herein by reference.

### BACKGROUND

### (i) Technical Field

The present invention relates to a semiconductor device.

### (ii) Related Art

There has been known a technique that covers a semiconductor element such as a Heterojunction Bipolar Transistor (HBT) using an InP-based compound semiconductor with a resin layer made of Benzocyclobutene (BCB) or the like as disclosed in Japanese Patent Application Publication No. 2014-116381.

### SUMMARY

The resin layer made of BCB or the like is deteriorated by oxygen and/or water. The deterioration changes the characteristics of the semiconductor element such as an HBT.

It is an object to provide a semiconductor device that inhibits the deterioration of a resin layer.

According to an aspect of the present invention, there is provided a semiconductor device including: a semiconductor element disposed on a semiconductor substrate; a first insulating film disposed on the semiconductor substrate, the first insulating film having an upper surface and an edge; a resin layer disposed on the semiconductor substrate, the resin layer covering the semiconductor element; and a second insulating film disposed on the semiconductor substrate, the second insulating film covering the upper and side surfaces of the resin layer. The second insulating film has an edge arranged apart from the side surface of the resin layer by a distance. The distance between the edge of the second insulating film and the side surface of the resin layer is greater than a film thickness of the second insulating film.

### BRIEF DESCRIPTION OF THE DRAWINGS

FIG. 1 is a top view of a semiconductor device in accordance with a first embodiment;

FIG. 2A is a cross-sectional view taken along line A-A in FIG. 1;

FIG. 2B is a cross-sectional view taken along line B-B in FIG. 1;

FIG. 3A is a cross-sectional view of a semiconductor device in accordance with a first comparative example;

FIG. 3B is a cross-sectional view of a semiconductor device in accordance with a second comparative example;

FIG. 3C is a cross-sectional view of the semiconductor device in accordance with the first embodiment;

FIG. 4A is a cross-sectional view (No. 1) illustrating a method of fabricating the semiconductor device in accordance with the first embodiment;

FIG. 4B is a cross-sectional views (No. 2) illustrating the method of fabricating the semiconductor device in accordance with the first embodiment;

FIG. 5A is a cross-sectional view (No. 3) illustrating the method of fabricating the semiconductor device in accordance with the first embodiment;

FIG. 5B is a cross-sectional view (No. 4) illustrating the method of fabricating the semiconductor device in accordance with the first embodiment;

FIG. 6A is a cross-sectional view (No. 5) illustrating the method of fabricating the semiconductor device in accordance with the first embodiment;

FIG. 6B is a cross-sectional view (No. 6) illustrating the method of fabricating the semiconductor device in accordance with the first embodiment;

FIG. 7A is a cross-sectional view (No. 7) illustrating the method of fabricating the semiconductor device in accordance with the first embodiment;

FIG. 7B is a cross-sectional view (No. 8) illustrating the method of fabricating the semiconductor device in accordance with the first embodiment;

FIG. 8A is a cross-sectional view (No. 9) illustrating the method of fabricating the semiconductor device in accordance with the first embodiment;

FIG. 8B is a cross-sectional view (No. 10) illustrating the method of fabricating the semiconductor device in accordance with the first embodiment;

FIG. 9A is a cross-sectional view (No. 11) illustrating the method of fabricating the semiconductor device in accordance with the first embodiment;

FIG. 9B is a cross-sectional view (No. 12) illustrating the method of fabricating the semiconductor device in accordance with the first embodiment;

FIG. 10A is a cross-sectional view (No. 13) illustrating the method of fabricating the semiconductor device in accordance with the first embodiment;

FIG. 10B is a cross-sectional view (No. 14) illustrating the method of fabricating the semiconductor device in accordance with the first embodiment;

FIG. 11A is a cross-sectional view (No. 15) illustrating the method of fabricating the semiconductor device in accordance with the first embodiment;

FIG. 11B is a cross-sectional view (No. 16) illustrating the method of fabricating the semiconductor device in accordance with the first embodiment;

FIG. 12A is a cross-sectional view (No. 17) illustrating the method of fabricating the semiconductor device in accordance with the first embodiment;

FIG. 12B is a cross-sectional view (No. 18) illustrating the method of fabricating the semiconductor device in accordance with the first embodiment;

FIG. 13A is a cross-sectional view (No. 19) illustrating the method of fabricating the semiconductor device in accordance with the first embodiment;

FIG. 13B is a cross-sectional view (No. 20) illustrating the method of fabricating the semiconductor device in accordance with the first embodiment;

FIG. 14A is a cross-sectional view (No. 21) illustrating the method of fabricating the semiconductor device in accordance with the first embodiment;

FIG. 14B is a cross-sectional view (No. 22) illustrating the method of fabricating the semiconductor device in accordance with the first embodiment;

FIG. 15 is a cross-sectional view of a semiconductor device in accordance with a second embodiment;

FIG. 16A is a cross-sectional view (No. 1) illustrating a method of fabricating the semiconductor device in accordance with the second embodiment;

FIG. 16B is a cross-sectional view (No. 2) illustrating the method of fabricating the semiconductor device in accordance with the second embodiment;

FIG. 16C is a cross-sectional view (No. 3) illustrating the method of fabricating the semiconductor device in accordance with the second embodiment;

FIG. 17 is a cross-sectional view of a semiconductor device in accordance with a third embodiment;

FIG. 18A is a cross-sectional view (No. 1) illustrating a method of fabricating the semiconductor device in accordance with the third embodiment;

FIG. 18B is a cross-sectional view (No. 2) illustrating the method of fabricating the semiconductor device in accordance with the third embodiment;

FIG. 18C is a cross-sectional view (No. 3) illustrating the method of fabricating the semiconductor device in accordance with the third embodiment;

FIG. 19 is a plan view of a semiconductor device in accordance with a fourth embodiment; and

FIG. 20 is a cross-sectional view taken along line A-A in FIG. 19.

### DETAILED DESCRIPTION

### Description of Embodiments of the Present Invention

First of all, the contents of embodiments of the present invention will be listed and described.

The present invention is a semiconductor device including: a semiconductor element disposed on a semiconductor substrate; a first insulating film disposed on the semiconductor substrate, the first insulating film having an upper surface and an edge; a resin layer disposed on the semiconductor substrate, the resin layer covering the semiconductor element; and a second insulating film disposed on the semiconductor substrate, the second insulating film covering the upper and side surfaces of the resin layer. The second insulating film has an edge arranged apart from the side surface of the resin layer by a distance. The distance between the side surface of the second insulating film and the side surface of the resin layer is greater than a film thickness of the second insulating film.

The second insulating film is in contact with the upper and side surfaces of the resin layer. This structure prevents the entrance of oxygen or the like from outside of the second insulating layer into the resin layer. Therefore, the deterioration of the resin layer can be avoided.

It is preferable that the edge of the first insulating film is in contact with the second insulating film, and the second insulating film is in contact with an upper surface of the semiconductor substrate in an outside of the resin layer. Since the second insulating film covers both the edge of the first insulating film and the upper surface of the semiconductor substrate in the outside of the resin layer, the entrance of oxygen or the like into the resin layer is reduced.

It is preferable that the edge of the first insulating film is located further out than the side surface of the resin layer, the first insulating film is in contact with the upper surface of the semiconductor substrate in an outside of the resin layer, and the second insulating film is in contact with the upper surface of the first insulating film in the outside of the resin layer. Since the first insulating film is in contact with the upper surface of the semiconductor substrate in the outside of the resin layer, and the second insulating film is in contact with the upper surface of the first insulating film in the outside of the resin layer, the entrance of oxygen or the like into the resin layer is reduced.

It is preferable that the edge of the first insulating film is exposed from the second insulating film. This structure has the long boundary face between the first insulating film and the semiconductor substrate, and thereby reduces the entrance of oxygen or the like into the resin layer from outside of the edge of the insulating films.

It is preferable that the second insulating film is in contact with the edge of the first insulating film. This structure prevents oxygen or the like from entering into the resin layer.

It is preferable that the first insulating film is a silicon oxide film, and the second insulating film is a silicon nitride film or a silicon oxynitride film. The penetration of oxygen or the like from the upper and side surfaces of the resin layer to the resin layer can be inhibited by adopting a silicon nitride film or a silicon oxynitride film as the second insulating film. The side-etching of the first insulating film during the fabrication steps can be inhibited by adopting a silicon oxide film as the first insulating film. Moreover, the entrance of oxygen or the like into the resin layer through the boundary face between the semiconductor substrate and the first insulating film may be reduced.

It is preferable that the resin layer is a BCB layer. The shrinkage in volume of the BCB layer due to oxidation can be inhibited by adopting the first and second insulating layers as mentioned above.

### First Embodiment

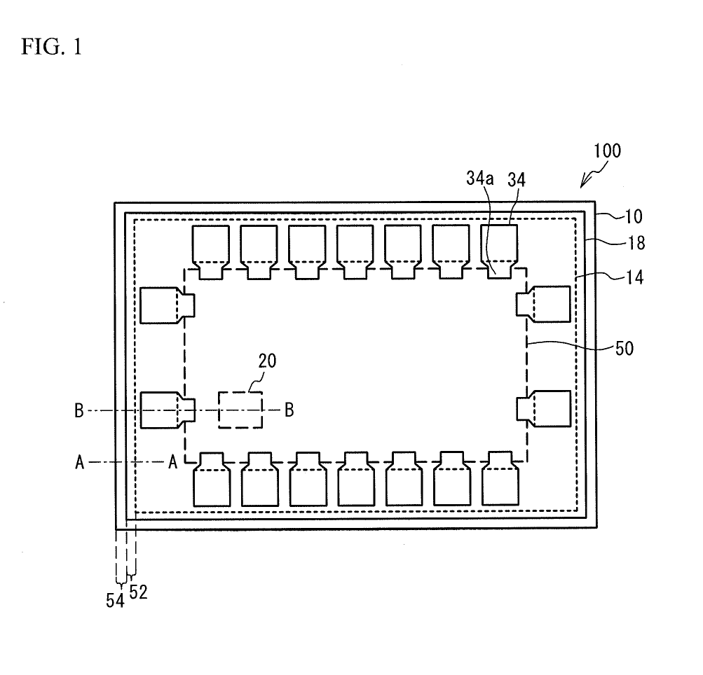

FIG. 1 is a top view of a semiconductor device in accordance with a first embodiment. As illustrated in FIG. 1, a semiconductor device 100 includes a circuit unit 50 disposed on a semiconductor substrate 10. The semiconductor substrate 10 may include a semiconductor layer formed on a substrate. The semiconductor device 100 includes a semiconductor element 20 located in the circuit unit 50. The circuit unit 50 amplifies electrical signals and/or switches electrical signals, for example. A resin layer 14 is located on the semiconductor substrate 10 so as to cover the circuit unit 50 to protect the circuit unit 50. An insulating film 18 is located on the semiconductor substrate 10 so as to cover the resin layer 14. Pads 34 are exposed from the resin layer 14 and the insulating film 18, and are electrically coupled to the circuit unit 50. The pad 34 is a bonding pad, and, for example, a bonding wire or the like for providing a connection to an external device is coupled to the pad 34. The pads 34 are arranged along the outer edge of the chip. A surface wiring layer 34a electrically couples the pads 34 to the circuit unit 50.

The insulating film 18 covers the semiconductor substrate 10 up as far as the outside of the resin layer 14. The insulating film 18 covers the upper surface of the semiconductor substrate 10 in a region 52. The region 52 is a region between the edge of the resin layer 14 and the edge of the insulating film 18. A region 54 is a region outside the region 52, and the semiconductor substrate 10 is exposed in the region 54. The region 54 is, for example, a scribe line used to separate devices from each other. Neither the resin layer 14 nor the insulating film 18 is located in the region 54, in order to prevent an undesirable cracking during the separation of devices. The chip has dimensions of, for example, 1×2 mm. The circuit unit 50 has dimensions of, for example, 0.8×1.8 mm. The pad 34 has dimensions of, for example, 70×70 μm.

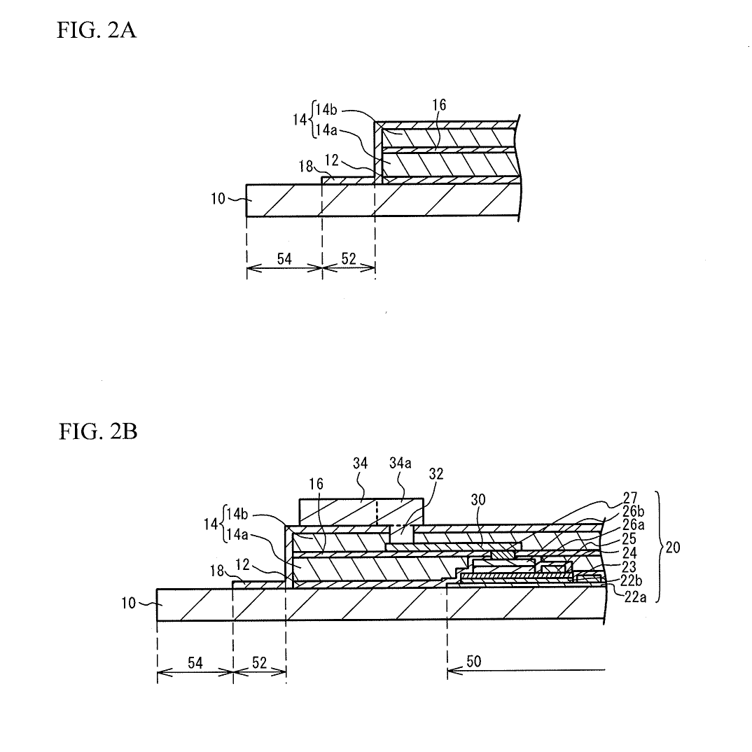

FIG. 2A is a cross-sectional view taken along line A-A in FIG. 1, and FIG. 2B is a cross-sectional view taken along line B-B in FIG. 1. As illustrated in FIG. 2A and FIG. 2B, the semiconductor element 20 is located on the semiconductor substrate 10. The semiconductor substrate 10 is, for example, an InP substrate, and the semiconductor element 20 is, for example, an InP-based HBT. The semiconductor element 20 includes a subcollector layer 22a, a collector layer 22b, a collector electrode 23, a base layer 24, a base electrode 25, an emitter layer 26a, an emitter contact layer 26b, and an emitter electrode 27. The subcollector layer 22a is located on the semiconductor substrate 10. The collector layer 22b is located on the subcollector layer 22a. The base layer 24 is located on the collector layer 22b. The emitter layer 26a is located on the base layer 24. The emitter contact layer 26b is located on the emitter layer 26a. The collector electrode 23 makes electrical contacts with the subcollector layer 22a, the base electrode 25 makes electrical contacts with the base layer 24, and the emitter electrode 27 makes electrical contacts with the emitter contact layer 26b. The collector layer 22b, the base layer 24, and the emitter layer 26a are respectively, for example, an InGaAs layer, an InGaAs layer, and an InP layer.

An insulating film 12 (a first insulating film) is located on the semiconductor substrate 10 so as to cover the semiconductor element 20. A resin layer 14a (a first resin layer) is located on the insulating film 12. An insulating film 16 (a third insulating film) is located on the resin layer 14a. An internal wiring layer 30 is located on the insulating film 16. The internal wiring layer 30 is electrically coupled to the emitter electrode 27. A resin layer 14b (a second resin layer) is located on the insulating film 16 so as to cover the internal wiring layer 30. The resin layer 14 includes the resin layers 14a and 14b. The insulating film 18 (a second insulating film) is located on the resin layer 14. The insulating film 18 is in contact with the upper and side surfaces of the resin layer 14 and the edge of the insulating film 12. The pad 34 is located on the insulating film 18. A penetration wiring line 32 penetrates through the resin layer 14b and the insulating film 18, and electrically couples the internal wiring layer 30 to the surface wiring layer 34a. This structure allows the pad 34 to be electrically coupled to the semiconductor element 20 through the surface wiring layer 34a, the penetration wiring line 32, and the internal wiring layer 30.

The insulating films 12, 16, and 18 are inorganic insulating films such as silicon oxide (SiO₂) films, silicon nitride films, or silicon oxynitride films. The resin layer 14 is a BCB layer or a polyimide layer. The internal wiring layer 30, the penetration wiring line 32, the pad 34, and the surface wiring layer 34a are formed of a metal layer such as a gold layer, a copper layer, or an aluminum layer. An exemplary case where the pad 34 is coupled to the emitter contact layer 26b has been described, but the pad 34 may be coupled to the base layer 24, the subcollector layer 22a, and/or other elements in the circuit unit 50. In the region 52, the insulating film 18 is in contact with the semiconductor substrate 10. In the region 54, the semiconductor substrate 10 is exposed.

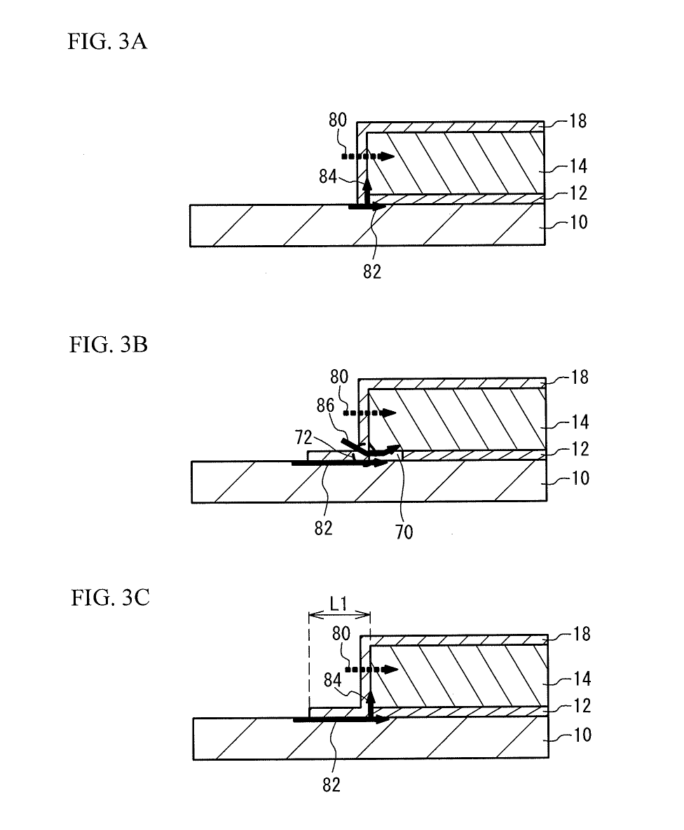

Advantages of the first embodiment will be described by comparing the first embodiment to comparative examples. FIG. 3A is a cross-sectional view of a semiconductor device in accordance with a first comparative example. FIG. 3A corresponds to the cross-section taken along line A-A in FIG. 1. In the first comparative example, an edge of the insulating film 18 is in contact with the semiconductor substrate 10. The insulating film 18 does not cover the upper surface of the semiconductor substrate 10.

In FIG. 3A (the first comparative example), a length of a boundary face 82 between the edge of the insulating film 18 and the upper surface of the substrate 10 is as short as the thickness of the insulating film 18. Oxygen and/or water may reach to the resin layer 14 from the outside of the insulating film 18 through the boundary face 82. The resin layer 14 may be oxidized by oxygen and/or water. The oxidization of the resin layer 14 causes a change of the stress applied to the semiconductor element 20. The change in stress changes the characteristics of the HBT element.

The inorganic insulating film is less likely to allow oxygen and/or water (hereinafter, described also as oxygen or the like) to penetrate therethrough than the resin layer 14. Thus, the entrance of oxygen or the like into the resin layer 14 through a pathway 80 hardly occurs. Oxygen or the like penetrates through the boundary faces (pathways 82 and 84) between the insulating films 12 and 18 and the semiconductor substrate 10 when the pathway 82 is short. Thus, in the first comparative example, oxygen or the like enters the resin layer 14 through the pathways 82 and 84.

FIG. 3B is a cross-sectional view of a semiconductor device in accordance with a second comparative example. FIG. 3B corresponds to the cross-section taken along line A-A in FIG. 1. In the second comparative example, the side surface of the insulating film 12 is located inside the resin layer 14. The edge of the insulating film 12 makes no contact with the insulating film 18. An air gap 70 is formed between the edge of the insulating film 12 and the insulating film 18. For example, when the insulating film 12 is side-etched at the time of etching the insulating film 12, the air gap 70 is formed.

In FIG. 3B (the second comparative example), since the air gap 70 exists in the end of the pathway 82, oxygen or the like that has entered through the pathway 82 directly enters the resin layer 14. In addition, a region 72 being in contact with the air gap 70 makes the film thickness of the insulating film 18 in the region 72 thin. Thus, oxygen or the like easily enters the resin layer 14 through a pathway 86

As described above, in the first and second comparative examples, the entrance of oxygen or the like into the resin layer 14 easily occurs.

FIG. 3C is a cross-sectional view of the semiconductor device in accordance with the first embodiment. As illustrated in FIG. 3C, in the first embodiment, the insulating film 12 (a first insulating film) containing an inorganic insulating material is located between the semiconductor substrate 10 and the resin layer 14. The insulating film 18 (a second insulating film) containing an inorganic insulating material is in contact with the upper and side surfaces of the resin layer 14. The insulating film 18 is in contact with the edge of the insulating film 12. Furthermore, a distance L1 between the edge of the insulating film 18 and the side surface of the resin layer 14 is greater than the film thickness of the insulating film 18.

This structure makes the pathway 82 longer than that of the first comparative example. Accordingly, compared to the first comparative example, the entrance of oxygen or the like through the pathway 82 is reduced. In addition, compared to the second comparative example, oxygen or the like that has reached below the resin layer 14 through the pathway 82 enters the resin layer 14 through the pathway 84. Accordingly, compared to the second comparative example, the entrance of oxygen or the like into the resin layer 14 can be reduced. Furthermore, since the insulating film 18 is in contact with the edge of the insulating film 12, the film quality of the insulating film 18 does not deteriorate and/or the film thickness does not become thin unlike those in the region 72 of the second comparative example. Therefore, the deterioration, such as oxidation, of the resin layer 14 can be reduced, and the change in characteristics of the semiconductor element 20 can be therefore reduced.

The edge of the insulating film 12 is aligned with the side surface of the resin layer 14. The insulating film 18 is in contact with the edge of the insulating film 12, and is in contact with the upper surface of the semiconductor substrate 10 in the outside of the resin layer 14. This structure makes the distance L1 of the boundary face 82 between the insulating film 18 and the semiconductor substrate 10 long. Thus, the entrance of oxygen or the like into the resin layer 14 through the pathway 82 can be inhibited. To inhibit the entrance of oxygen or the like through the pathway 82, the distance L1 is preferably more than twice the film thicknesses of the insulating films 12 and 18, more preferably more than five times the film thicknesses of the insulating films 12 and 18, further preferably 1 μm or greater.

To inhibit the penetration of oxygen through the insulating films 12, 16 and 18, the insulating films 12, 16, and 18 are preferably silicon oxide films, silicon nitride films, or silicon oxynitride films. To inhibit the penetration of oxygen or the like, especially a silicon nitride film or a silicon oxide nitride film is preferable. The insulating films 12 and 18 preferably have film thicknesses of 100 nm or greater to inhibit the penetration of oxygen or the like. To inhibit the peeling of the film from the resin layer 14, the insulating films 12 and 18 preferably have film thicknesses of 1000 nm or less.

When the resin layer 14 is a BCB layer, the resin layer 14 tends to shrink in volume by the existence of oxygen or the like. The resin layer 14 preferably has a thickness of 0.5 μm or greater to protect the semiconductor element 20. The resin layer 14 preferably has a thickness of 10 μm or less to make the device size smaller. The resin layer 14 may be, for example, a polyimide layer.

In FIG. 2A and FIG. 2B, the side surface of the resin layer 14 is substantially perpendicular to the upper surface of the semiconductor substrate 10. The side surface of the resin layer 14 may be inclined with respect to the upper surface of the semiconductor substrate 10. For example, the side surface of the resin layer 14 may be inclined with respect to the upper surface of the semiconductor substrate 10 by approximately 70°. The side surface of the resin layer 14 may be flat or curved. When the side surface of the resin layer 14 is inclined or when the side surface of the resin layer 14 is curved, the distance L1 may be a distance between the bottom of the side surface of the resin layer 14 and the side surface of the insulating film 18. Fabrication Method of First Embodiment

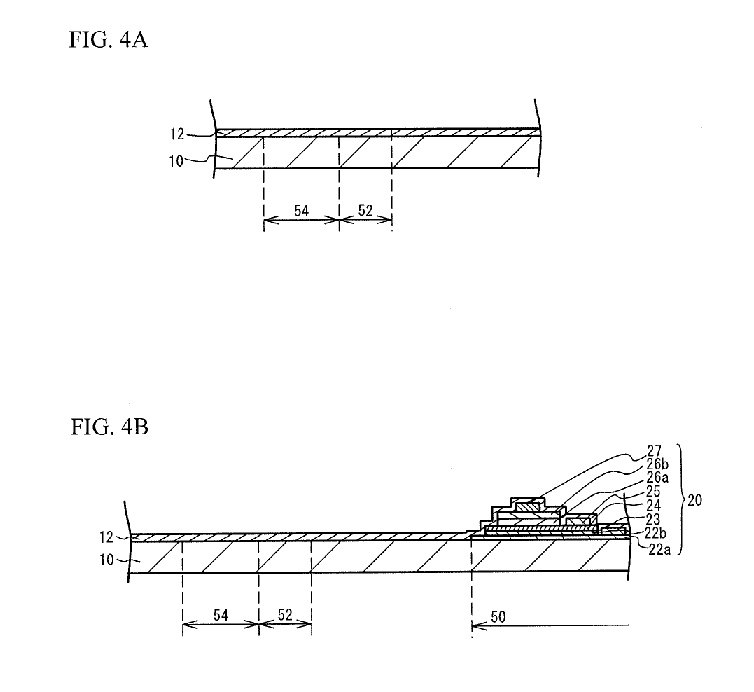

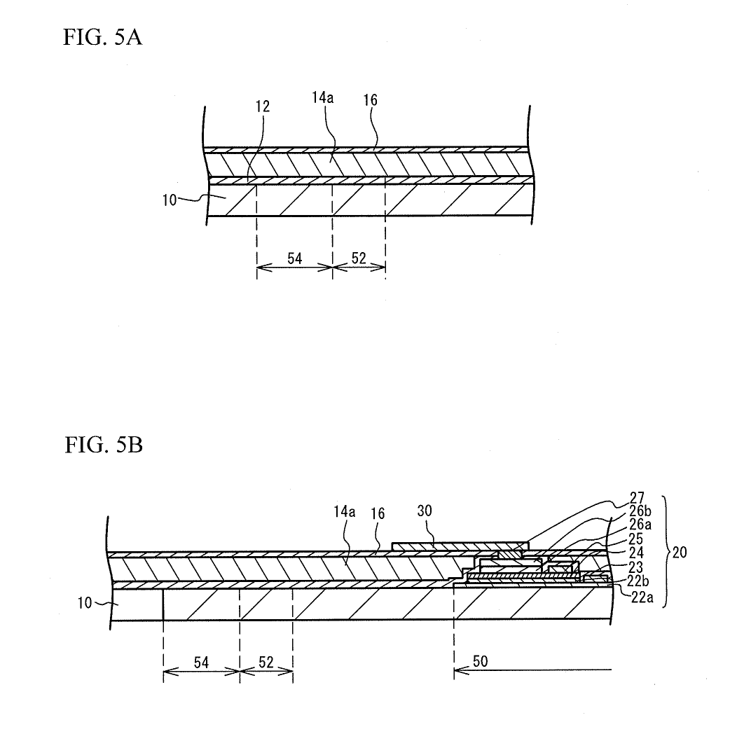

FIG. 4A through FIG. 14B are cross-sectional views illustrating a method of fabricating the semiconductor device in accordance with the first embodiment. FIG. 4A corresponds to the cross-section taken along line A-A in FIG. 1, and FIG. 4B corresponds to the cross-section taken along line B-B in FIG. 1. The same applies to FIG. 5A through FIG. 14B.

As illustrated in FIG. 4A and FIG. 4B, the semiconductor element 20 is formed on the semiconductor substrate 10. The insulating film 12 is formed on the semiconductor substrate 10 so as to cover the semiconductor element 20. The insulating film 12 is, for example, a silicon dioxide (SiO₂) film, and formed by thermal Chemical Vapor Deposition (CVD). The insulating film 12 has a film thickness of, for example, 200 nm.

As illustrated in FIG. 5A and FIG. 5B, the resin layer 14a is formed on the insulating film 12. For example, BCB resin is spin coated on the insulating film 12. Then, the BCB resin is thermally hardened by heat treatment. This process forms, for example, the resin layer 14a with a film thickness of 1 μm. The insulating film 16 is formed on the resin layer 14a. The insulating film 16 is, for example, a silicon dioxide film, and is formed by thermal CVD. The insulating film 16 has a film thickness of, for example, 300 nm. A penetration hole connecting to the semiconductor element 20 is formed in the insulating film 16 and the resin layer 14a. The internal wiring layer 30 is formed in the penetration hole and on the insulating film 16.

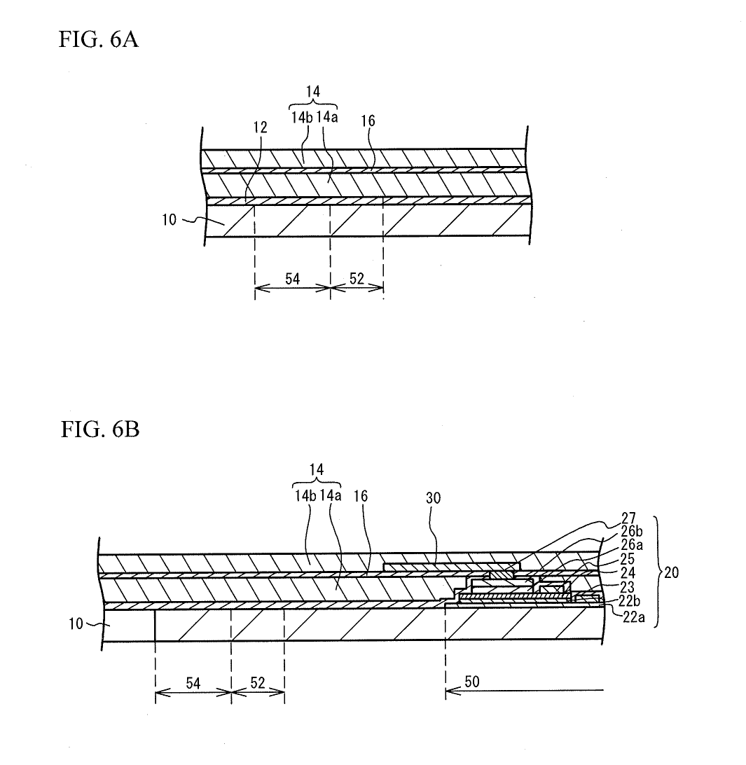

As illustrated in FIG. 6A and FIG. 6B, the resin layer 14b is formed on the insulating film 16 so as to cover the internal wiring layer 30. A method of forming the resin layer 14b is the same as the method of forming the resin layer 14a. The resin layer 14b has a film thickness of, for example, 1 μm. The resin layers 14a and 14b form the resin layer 14.

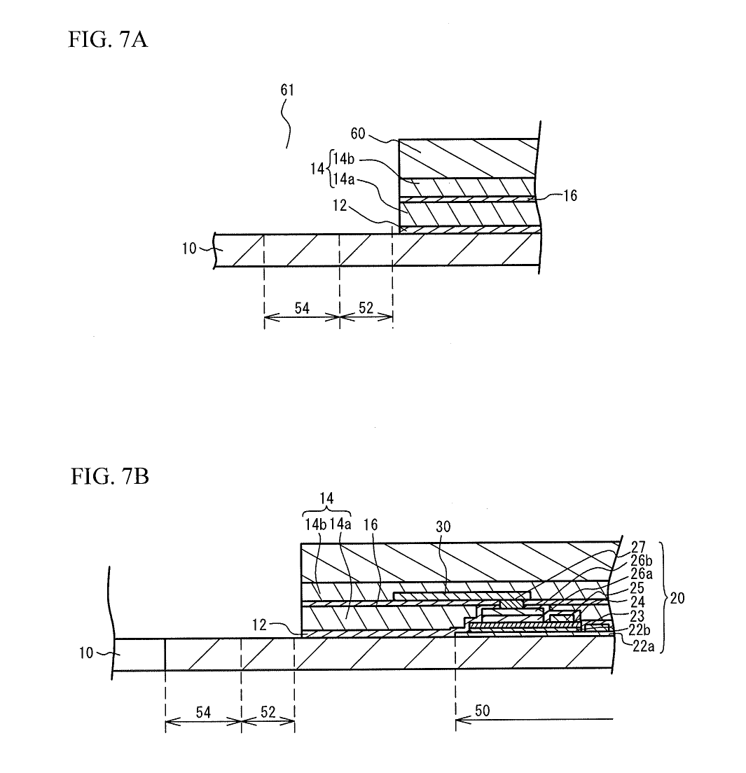

As illustrated in FIG. 7A and FIG. 7B, a mask layer 60 is formed on the resin layer 14. The mask layer 60 is formed of, for example, photoresist, and includes an opening 61 in the regions 52 and 54. The resin layer 14b, the insulating film 16, the resin layer 14a, and the insulating film 12 are etched using the mask layer 60 as a mask. The etching is performed by dry etching using, for example, CF₄ gas. When the insulating films 12 and 16 are silicon dioxide films, neither the insulating film 12 nor 16 is side-etched even when the resin layers 14a and 14b and the insulating films 12 and 16 are continuously etched. This is because the dry etching of silicon oxide is assisted by ions accelerated in the vertical direction, and therefore hardly proceeds in the lateral direction. The upper surface of the semiconductor substrate 10 is exposed. The mask layer 60 is then removed.

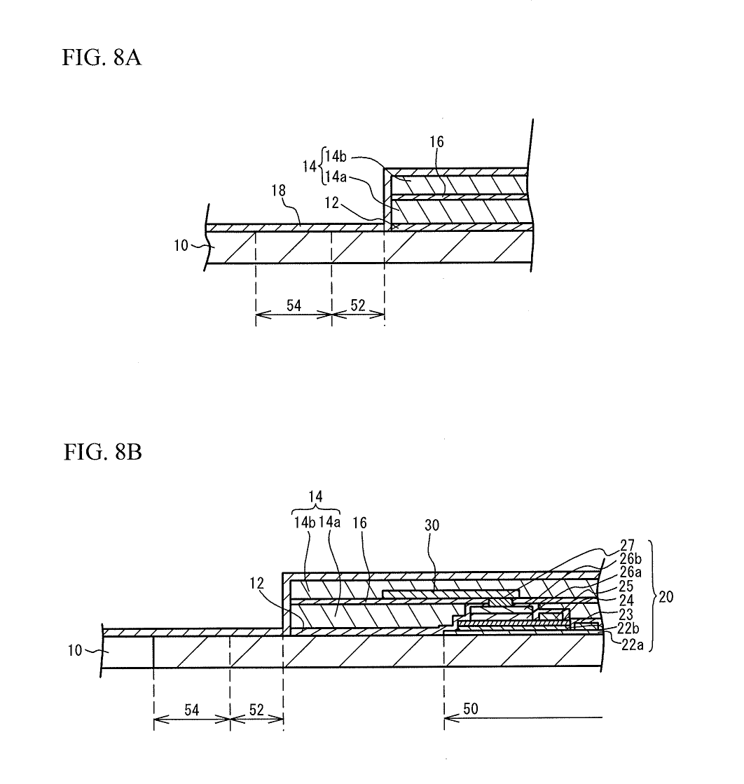

As illustrated in FIG. 8A and FIG. 8B, the insulating film 18 is formed on the semiconductor substrate 10 so as to cover the resin layer 14. The insulating film 18 is, for example, a silicon nitride film, and is formed by plasma CVD. The insulating film 18 has a film thickness of, for example, 300 nm. The insulating film 18 is located so as to be in contact with the semiconductor substrate 10 in the regions 52 and 54.

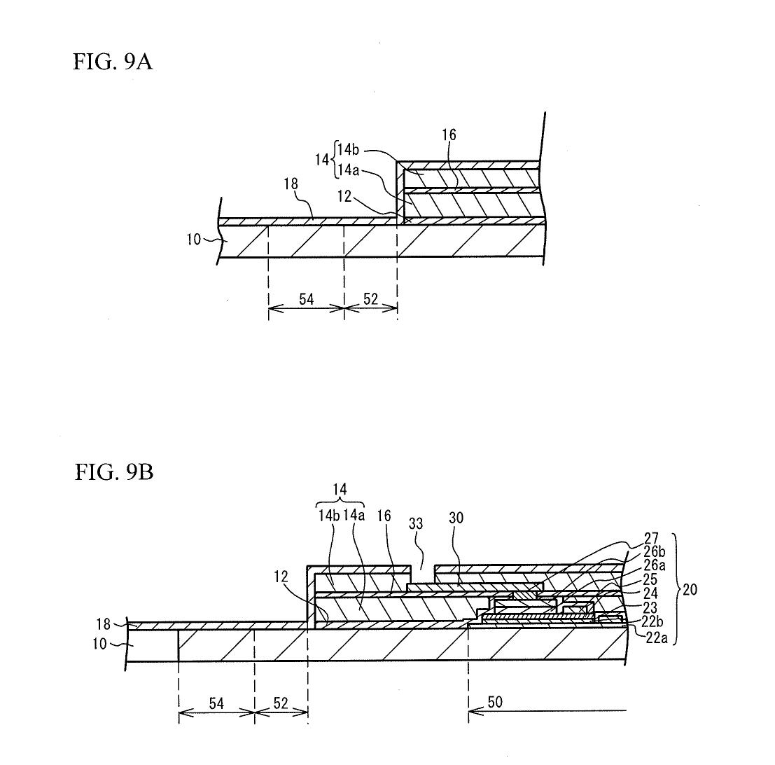

As illustrated in FIG. 9A and FIG. 9B, a penetration hole 33 penetrating through the insulating film 18 and the resin layer 14b is formed so that a part of the upper surface of the internal wiring layer 30 is exposed. The penetration hole 33 is formed by photolithography and dry etching.

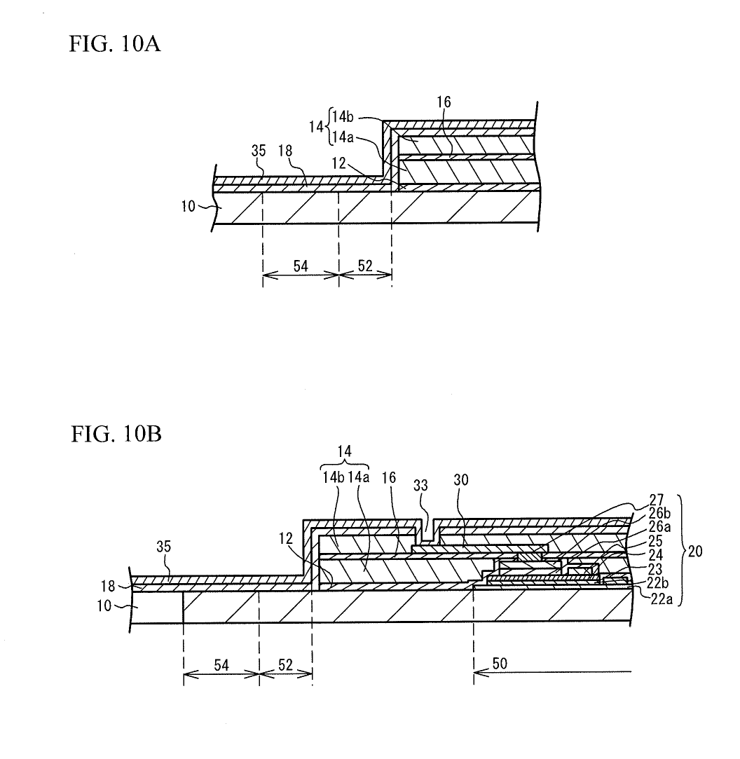

As illustrated in FIG. 10A and FIG. 10B, an undercoat layer 35 is formed on the insulating film 18 and in the penetration hole 33. The undercoat layer 35 is formed of, for example, a TiW film with a film thickness of 50 nm, a platinum layer with a film thickness of 30 nm, and a gold layer with a film thickness of 200 nm stacked in this order on the insulating film 18 side, and is formed by, for example, sputtering.

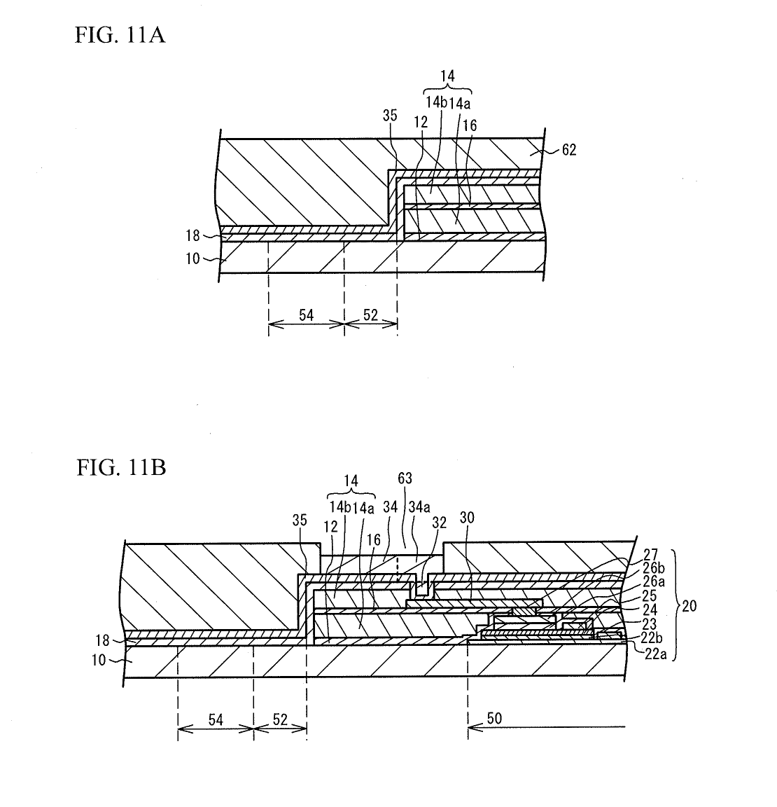

As illustrated in FIG. 11A and FIG. 11B, a mask layer 62 including an opening 63 is formed on the undercoat layer 35. The opening 63 of the mask layer 62 is formed in an area to be the pad 34 and the surface wiring layer 34a. The mask layer 62 is made of, for example, photoresist. The pad 34 and the surface wiring layer 34a are formed in the opening 63 of the mask layer 62 by electrolytic plating by supplying electric current through the undercoat layer 35. The pad 34 and the surface wiring layer 34a are formed of, for example, a gold layer with a film thickness of 5 μm.

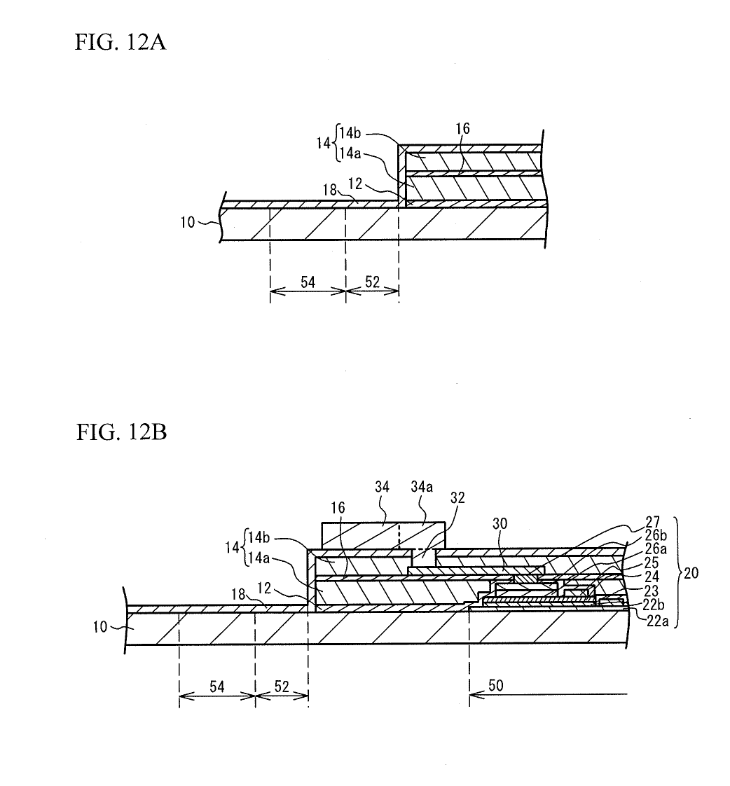

As illustrated in FIG. 12A and FIG. 12B, the mask layer 62 is removed. The undercoat layer 35 exposed from the pad 34 and the surface wiring layer 34a is removed by etching such as ion milling. In the drawings hereinafter, the illustration of the undercoat layer 35 is omitted. This process forms the pad 34 and the surface wiring layer 34a.

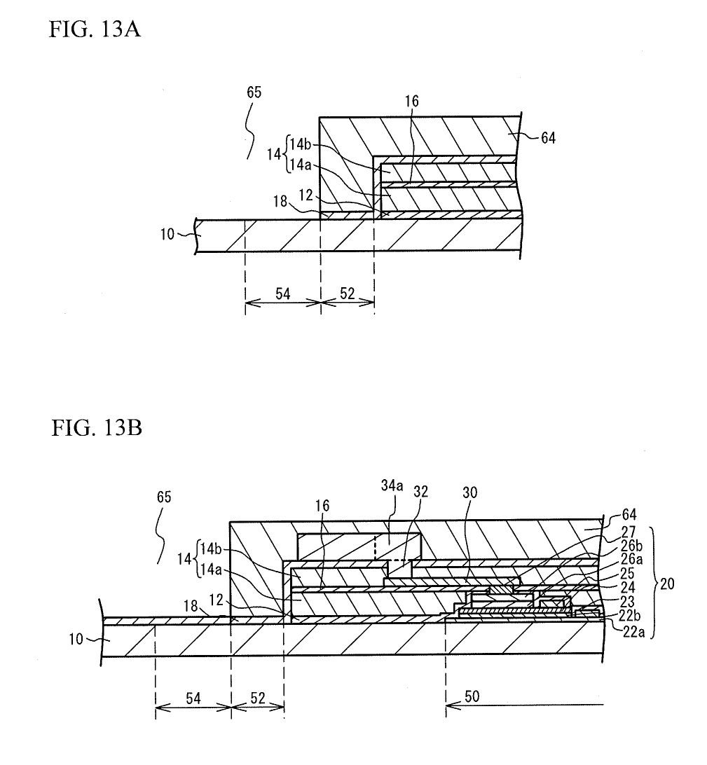

As illustrated in FIG. 13A and FIG. 13B, a mask layer 64 is formed on the insulating film 18. The mask layer 64 is made of, for example, photoresist, and includes an opening 65 in the region 54. The insulating film 18 is etched using the mask layer 64 as a mask. The etching is performed by, for example, dry etching using CF₄ gas. The upper surface of the semiconductor substrate 10 in the region 54 is exposed. In the region 52, the insulating film 18 being in contact with the semiconductor substrate 10 remains. The mask layer 64 is then removed.

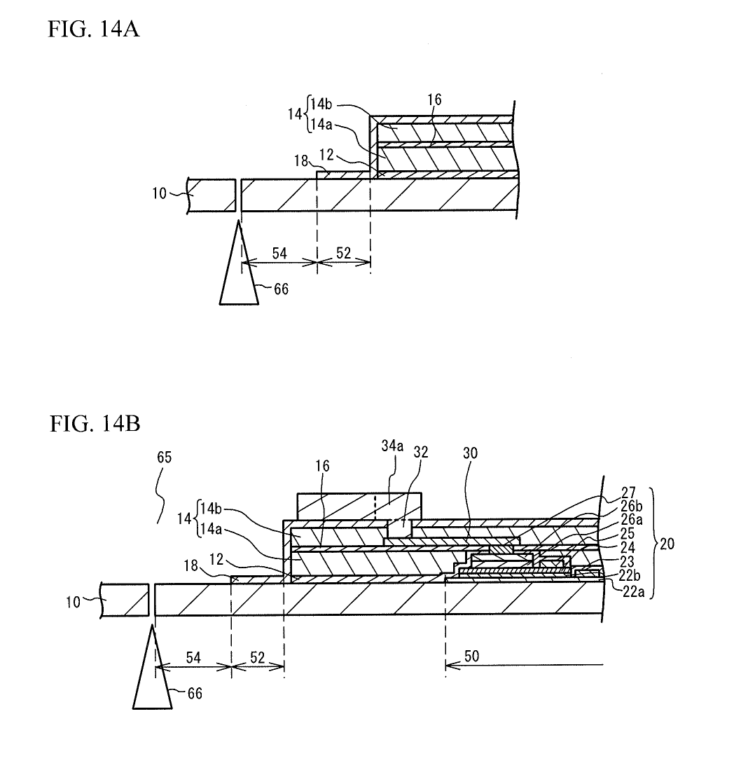

As illustrated in FIG. 14A and FIG. 14B, in the region 54, the semiconductor substrate 10 is separated. The semiconductor substrate 10 is cleaved by using, for example, a scribe tool. The semiconductor substrate 10 may be separated by laser scribing or dicing instead of scribing.

As illustrated in FIG. 7A and FIG. 7B, the resin layer 14 and the insulating film 12 are etched so that the side surface of the resin layer 14 aligns with the side surface (the edge) of the insulating film 12. This process allows the insulating film 18 to be formed so as to be in contact with the side surface of the insulating film 12 as illustrated in FIG. 8A and FIG. 8B. Therefore, the deterioration of the film quality of the insulating film 18 and/or the decrease in the film thickness of the insulating film 18, which may occur owing to the side-etching of the insulating film 12, can be inhibited.

To inhibit the penetration of oxygen or the like, the insulating film 18 is preferably a silicon nitride film or a silicon oxide nitride film. However, when the insulating film 12 is a silicon nitride film or a silicon oxide nitride film, the insulating film 12 is side-etched in the fabrication step shown in FIG. 7A and FIG. 7B. This is because the reaction rate between silicon nitride and a fluorine gas, which is an etching gas, is larger than the reaction rate between silicon oxide and the fluorine gas. The side-etching of the insulating film 12 results in the structure illustrated in FIG. 3B of the second comparative example. In the structure of the second comparative example, the film quality of the insulating film 18 in the region 72 of FIG. 3B is bad and/or the film thickness of the insulating film 18 in the region 72 of FIG. 3B is thin.

Therefore, the insulating film 12 is preferably made of a material with an etching rate less than that of the insulating film 16. A silicon oxide film that has a small reaction rate with a fluorine-based gas may be used for the insulating film 12. The use of the silicon oxide film avoids a side-etching in the insulating film 12 during the dry etching step of the resin layer 14 and the insulating film 16. The insulating film 12 may be the same film as the insulating film 18. In this case, the insulating film 12 is preferably deposited by CVD on the substrate under the condition that the insulating film 12 has a higher density than that of the insulating film 16.

As illustrated in FIG. 4A and FIG. 4B, the insulating film 12 preferably covers the semiconductor element 20. This structure allows the semiconductor element 20 to be protected in the subsequent fabrication steps.

The resin layer 14 includes the resin layers 14a (a first resin layer) and 14b (a second resin layer). The insulating film 16 (a third insulating film) is located between the resin layers 14a and 14b. This structure allows the internal wiring layer 30 to be formed on the insulating film 16 as illustrated in FIG. 5A and FIG. 5B. The insulating film 16 may not necessarily be formed, or two or more layers of the insulating film 16 may be formed.

In FIG. 14A and FIG. 14B, when the insulating films 12 and 18 remain in the region 54, a crack is formed in the insulating film 12 or 18 at the time of scribing. Alternatively, the insulating film 12 or 18 becomes a debris, and adheres to other regions. In the first embodiment, since neither the insulating film 12 nor 18 is located in the region 54, a crack can be inhibited from being formed in the insulating film 12 or 18, or a debris of the insulating films 12 and 18 can be inhibited.

### Second Embodiment

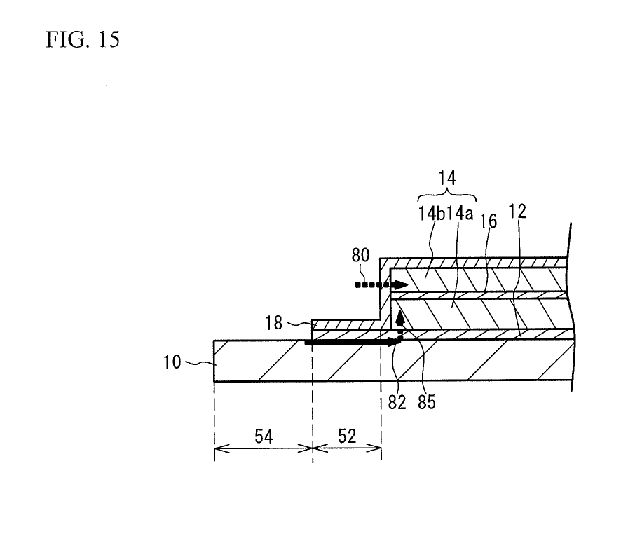

FIG. 15 is a cross-sectional view of a semiconductor device in accordance with a second embodiment. FIG. 15 corresponds to the cross-section taken along line A-A in FIG. 1. As illustrated in FIG. 15, the insulating film 12 being in contact with the upper surface of the semiconductor substrate is located in the region 52. In the region 52, the insulating film 18 is in contact with the upper surface of the insulating film 12. Other structures are the same as those of the first embodiment, and the description thereof is thus omitted.

The length of the boundary face between the insulating films 12 and 18 is approximately the same as the length of the boundary face between the insulating film 12 and the semiconductor substrate 10 (arrow 82). Oxygen or the like hardly enters the boundary face between the insulating film 12 and 18 compared to the boundary face between the semiconductor substrate 10 and the insulating films 12. Oxygen or the like hardly enters the resin layer 14, since a single layer of the insulating film 12 prevents the oxygen from penetrating.

As described above, in the second embodiment, the edge of the insulating film 12 is located further out than the side surface of the resin layer 14. The insulating film 12 is in contact with the upper surface of the semiconductor substrate 10 in the outside of the resin layer 14. Furthermore, the insulating film 18 is in contact with the upper surface of the insulating film 12 in the outside of the resin layer 14. This structure can inhibit the entrance of oxygen or the like through the pathway 85 even when oxygen or the like might enter through the pathway 82. Therefore, the deterioration, such as oxidation, of the resin layer 14 can be inhibited, and the change in characteristics of the semiconductor element 20 can be therefore inhibited.

In addition, the edge of the insulating film 12 is aligned with the edge of the insulating film 18. The edge of the insulating film 12 is exposed from the insulating film 18. This structure can make the boundary face between the insulating film 12 and the semiconductor substrate 10 long. Thus, the entrance of oxygen or the like into the resin layer 14 can be reduced.

Whether oxygen or the like that has penetrated through the pathway 82 enters depends on the type of the insulating film 12. According to the findings of the inventors, when the insulating film 12 is a silicon oxide film, the entrance of oxygen or the like through the pathway 82 is inhibited compared to when the insulating film 12 is a silicon nitride film or a silicon oxide nitride film. Therefore, the insulating film 12 is preferably a silicon oxide film.

### Fabrication Method of Second Embodiment

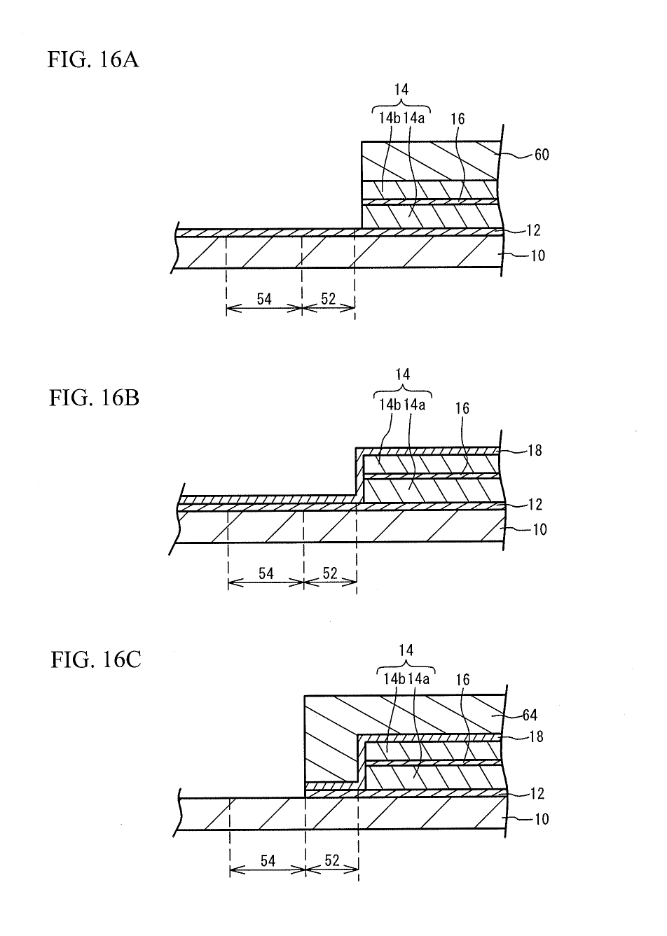

FIG. 16A through FIG. 16C are cross-sectional views illustrating a method of fabricating the semiconductor device in accordance with the second embodiment. As illustrated in FIG. 16A, the insulating film 12 remains when the resin layer 14 and the insulating film 16 are dry-etched. For example, a mixed gas of carbon tetrafluoride (CF₄) and oxygen (O₂) is used as an etching gas. When an oxygen mixture ratio is increased, the etching rate of silicon oxide (the insulating film 12) decreases with respect to the etching ratio of BCB (the resin layer 14). The dry-etching can be controlled to stop before the insulating film 12 is etched.

As illustrated in FIG. 16B, the insulating film 18 is formed so as to be in contact with the upper and side surfaces of the resin layer 14 and the insulating film 12 in the regions 52 and 54. As illustrated in FIG. 16C, the insulating films 12 and 18 in the region 54 are etched using the mask layer 64 as a mask. Other fabrication steps are the same as those of the first embodiment, and the description thereof is thus omitted.

In the second embodiment, the edge of the insulating film 12 aligns with the edge of the insulating film 18. This is because the insulating films 12 and 18 are simultaneously etched as illustrated in FIG. 16C.

### Third Embodiment

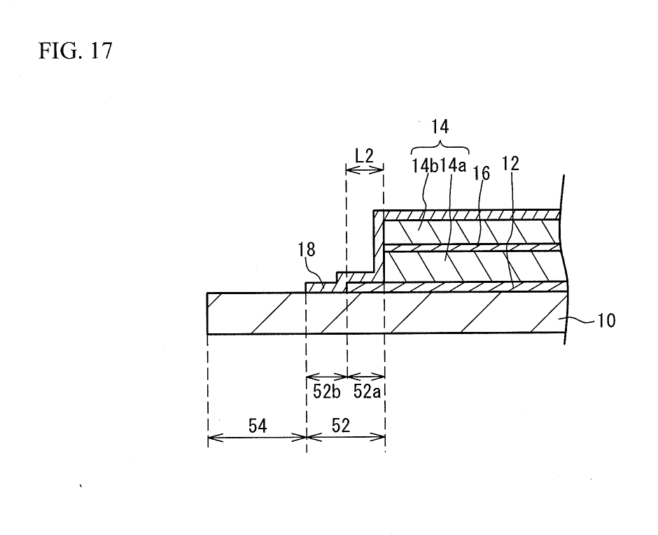

FIG. 17 is a cross-sectional view of a semiconductor device in accordance with a third embodiment. FIG. 17 corresponds to the cross-section taken along line A-A in FIG. 1. As illustrated in FIG. 17, the region 52 includes a region 52a and a region 52b located outside the region 52a.

In the region 52a, the insulating film 12 is in contact with the upper surface of the semiconductor substrate 10, and the insulating film 18 is in contact with the upper surface of the insulating film 12. In the region 52b, no insulating film 12 is formed, and the insulating film 18 is in contact with the upper surface of the semiconductor substrate 10. Other structures are the same as those of the first embodiment, and the description thereof is thus omitted.

### Fabrication Method of Third Embodiment

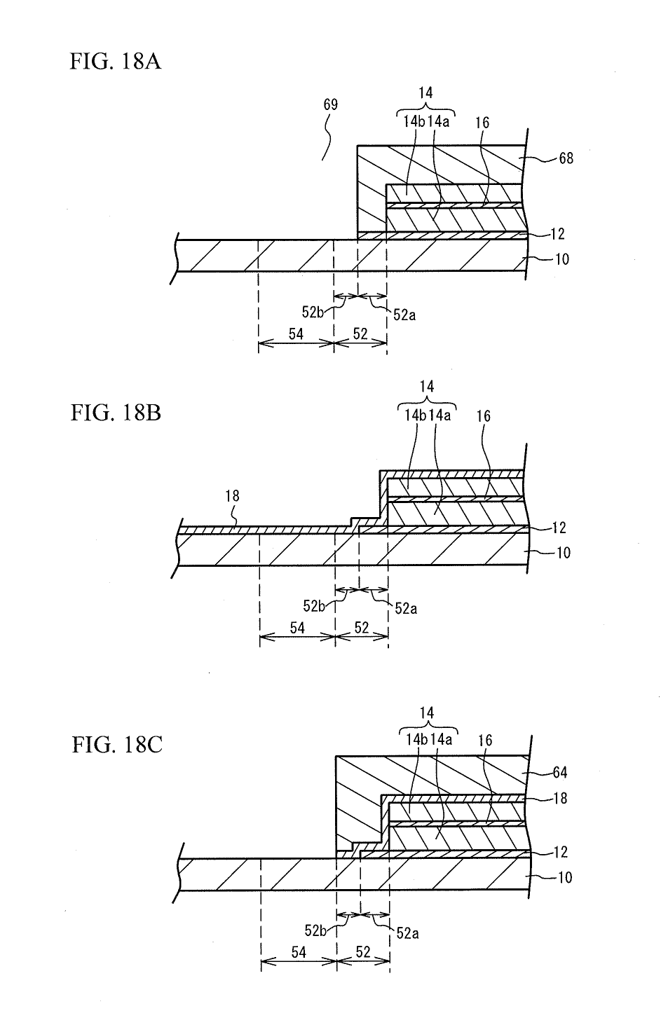

FIG. 18A through FIG. 18C are cross-sectional views illustrating a method of fabricating the semiconductor device in accordance with the third embodiment. As illustrated in FIG. 18A, after the mask layer 60 is removed after the step illustrated in FIG. 16A of the second embodiment, a mask layer 68 is formed on the resin layer 14 and the insulating film 12. The mask layer 68 is made of, for example, photoresist, and includes an opening 69 in the regions 52b and 54. The insulating film 12 is etched using the mask layer 68 as a mask. The mask layer 68 is then removed.

As illustrated in FIG. 18B, the insulating film 18 is formed so as to be in contact with the upper and side surfaces of the resin layer 14, the upper surface of the insulating film 12 in the region 52a, and the upper surface of the semiconductor substrate 10 in the regions 52b and 54. As illustrated in FIG. 18C, the insulating film 12 in the region 54 is etched using the mask layer 64 as a mask. Other fabrication steps are the same as those of the first embodiment, and the description thereof is thus omitted.

In the third embodiment, in the region 52a, the insulating film 12 is in contact with the upper surface of the semiconductor substrate 10 in the outside of the resin layer 14. The insulating film 18 is in contact with the upper surface of the insulating film 12 in the outside of the resin layer 14. This structure can inhibit the deterioration, such as oxidation, of the resin layer 14, and therefore inhibit the change in characteristics of the semiconductor element 20 as in the second embodiment.

To inhibit the entrance of oxygen or the like, a distance L2 (see FIG. 17) between the side surface of the resin layer 14 and the side surface of the insulating film 12 is preferably more than twice the film thicknesses of the insulating films 12 and 18, more preferably 1 μm or greater.

In FIG. 18B, since the insulating film 12 is etched using the mask layer 68 as a mask, the insulating film 12 can be inhibited from being side-etched. In addition, even when the insulating film 12 is side-etched, the insulating film 18 is in contact with the side surface of the insulating film 12. Therefore, the penetration of oxygen or the like through the air gap 70 described in the second comparative example can be inhibited.

### Fourth Embodiment

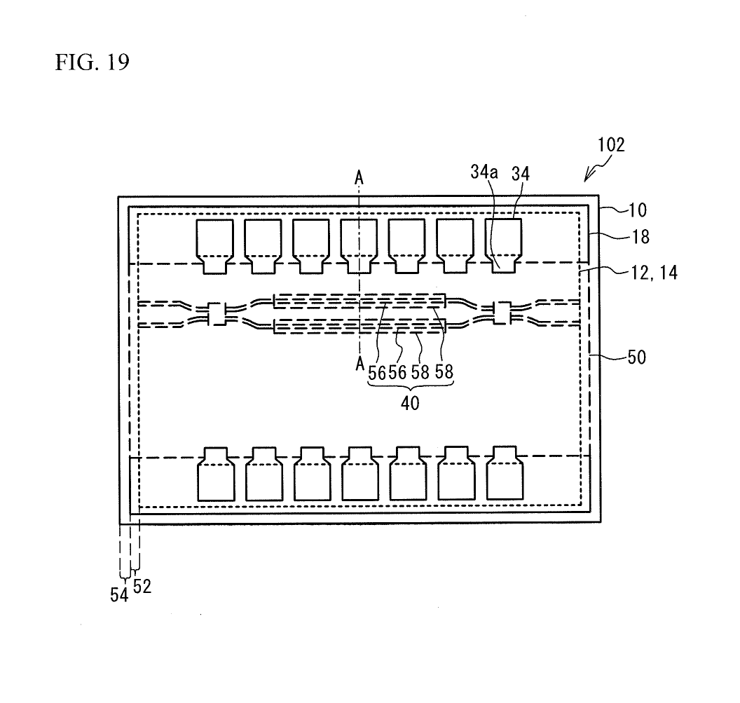

FIG. 19 is a plan view of a semiconductor device in accordance with a fourth embodiment. As illustrated in FIG. 19, in a semiconductor device 102, a mach-zehnder modulator as a semiconductor element 40 is formed on the semiconductor substrate 10. The semiconductor element 40 includes waveguides 56 and electrodes 58. The chip, which is a semiconductor device, has dimensions of, for example, 1×8 mm. The circuit unit 50 has dimensions of, for example, 0.8×7.8 mm.

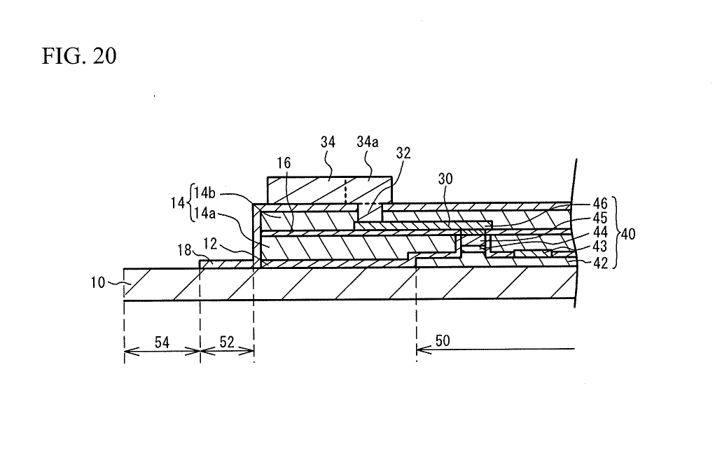

FIG. 20 is a cross-sectional view taken along line A-A in FIG. 19. As illustrated in FIG. 20, the semiconductor element 40 includes a lower cladding layer 42, a lower electrode 43, a core layer 44, an upper cladding layer 45, and an upper electrode 46. The lower cladding layer 42 is located on the semiconductor substrate 10. The core layer 44 is located on the lower cladding layer 42. The upper cladding layer 45 is located on the core layer 44. The lower electrode 43 makes electrical contacts with the lower cladding layer 42, and the upper electrode 46 makes electrical contacts with the upper cladding layer 45. The lower cladding layer 42 is, for example, an n-type InP layer, and the core layer 44 is, for example, a GaInAsP layer. The upper cladding layer 45 is formed of a p-type InP layer and a p-type InGaAs layer stacked in this order from the semiconductor substrate 10 side.

The waveguide 56 in FIG. 19 includes the lower cladding layer 42, the core layer 44 and the upper cladding layer 45. The electrode 58 in FIG. 19 includes the lower electrode 43 and the upper electrode 46. Other structures are the same as those of the first embodiment, and the description thereof is thus omitted.

In the first through fourth embodiments, the uppermost surface of the semiconductor substrate 10 is a compound semiconductor. The boundary faces between the compound semiconductor and the insulating films 12 and 18 are insufficient to prevent entering of oxygen or the like into the resin layer 14. Thus, the insulating film 18 is located so as to be in contact with the upper and side surfaces of the resin layer 14. The insulating film 18 is in contact with at least one of the upper surface and the edge of the insulating film 12. In addition, it is effective to make the distance between the edge of the insulating film 18 and the side surface of the resin layer 14 greater than the film thickness of the insulating film 18. This structure can inhibit oxygen or the like from entering the resin layer 14.

In addition, the characteristics of the semiconductor elements 20 and 40 each including a compound semiconductor layer may be changed by stress. For example, when a stress is applied to a compound semiconductor layer, the refractive index of the compound semiconductor layer changes, and/or piezoelectric charge is generated in the compound semiconductor layer. Therefore, the inhibition of the entrance of oxygen or the like into the resin layer 14 prevents characteristics of the semiconductor elements 20 and 40 from changing.

Especially the boundary faces between the insulating film and InP may be a pathway of oxygen or the like from outside into the resin layer. Therefore, when the semiconductor substrate 10 is made of InP, the first through fourth embodiments produce the effect more.

The semiconductor element 20 may include a transistor including a compound semiconductor layer such as the subcollector layer 22a, the collector layer 22b, the base layer 24, the emitter layer 26a, or the emitter contact layer 26b as in the first embodiment. The semiconductor element 40 may include the waveguide 56 including a compound semiconductor layer such as the lower cladding layer 42, the core layer 44, or the upper cladding layer 45 as in the fourth embodiment. The semiconductor element 20 may include a semiconductor element other than the transistor and the waveguide.

The present invention is not limited to the specifically disclosed embodiments and variations but may include other embodiments and variations without departing from the scope of the present invention.

What is claimed is:

1. A semiconductor device comprising:
a semiconductor element disposed on a semiconductor substrate;
a first insulating film disposed on the semiconductor substrate, the first insulating film having an upper surface and an edge;
a resin layer disposed on the semiconductor substrate, the resin layer covering the semiconductor element; and
a second insulating film disposed on the semiconductor substrate, the second insulating film covering the upper and side surfaces of the resin layer,
wherein the second insulating film has an edge arranged apart from the side surface of the resin layer by a distance, and
the distance between the edge of the second insulating film and the side surface of the resin layer is greater than a film thickness of the second insulating film.

2. The semiconductor device according to claim 1, wherein
the edge of the first insulating film is in contact with the second insulating film, and
the second insulating film is in contact with an upper surface of the semiconductor substrate in an outside of the resin layer.

3. The semiconductor device according to claim 1, wherein
the edge of the first insulating film is located further out than the side surface of the resin layer,
the first insulating film is in contact with an upper surface of the semiconductor substrate in an outside of the resin layer, and
the second insulating film is in contact with the upper surface of the first insulating film in the outside of the resin layer.

4. The semiconductor device according to claim 3, wherein the edge of the first insulating film is exposed from the second insulating film.

5. The semiconductor device according to claim 1, wherein
the edge of the first insulating film is located further out than the side surface of the resin layer,
the first insulating film is in contact with an upper surface of the semiconductor substrate in an outside of the resin layer,
the second insulating film is in contact with the upper surface of the first insulating film in the outside of the resin layer, and
the edge of the first insulating film is covered with the second insulating film.

6. The semiconductor device according to claim 1, wherein the first insulating film is a silicon oxide film, and the second insulating film is a silicon nitride film or a silicon oxynitride film.

7. The semiconductor device according to claim 1, wherein the resin layer is a BCB layer.

8. The semiconductor device according to claim 1, wherein the side surface of the resin layer aligns with the edge of the first insulating film.

9. The semiconductor device according to claim 1, wherein
the resin layer includes a first resin layer and a second resin layer,
the semiconductor device includes a third insulating film located between the first resin layer and the second resin layer, and
the third insulating film includes an inorganic insulating material.

10. The semiconductor device according to claim 1, further comprising a bonding pad located on the resin layer.

11. The semiconductor device according to claim 1, wherein the semiconductor element includes a transistor including a compound semiconductor layer.

12. The semiconductor device according to claim 1, wherein the semiconductor element includes an optical waveguide including a compound semiconductor layer.
